(19) United States
(12) Patent Application Publication
(10) Pub. No.: US 2009/0057845 A1
(43) Pub. Date: Mar. 5, 2009

(54) APPARATUS TO SAW WAFER AND HAVING NOZZLE TO REMOVE BURRS IN SCRIBE LANES, METHOD OF SAWING WAFER, AND SEMICONDUCTOR PACKAGE FABRICATED BY THE SAME

(75) Inventors: Ji-Sun Hong, Dangjin-gun (KR); Seung-Kon Mok, Cheonan-si (KR); Tae-Hun Kim, Cheonan-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/204,029

(22) Filed: Sep. 4, 2008

(30) Foreign Application Priority Data
Sep. 4, 2007 (KR) 2007-89409

(51) Int. Cl. H01L 23/48; H01L 21/304; B26D 7/08

(52) U.S. Cl. 257/621; 438/462; 83/168; 257/E23.01; 257/E21.238

(57) ABSTRACT

An apparatus to saw a wafer and having a nozzle to remove burrs in scribe lanes, a method of sawing a wafer, and a semiconductor package fabricated by the same. The apparatus includes a blade to cut scribe lanes of the wafer and a burr removing nozzle disposed spaced apart from the blade. The burr removing nozzle removes metal burrs generated adjacent to the blade during cutting the wafer.

### CROSS-REFERENCE TO RELATED APPLICATIONS

This U.S. nonprovisional patent application claims priority under 35 U.S.C. §119 of Korean Patent Application 2007-0089409 filed on Sep. 4, 2007, the entire contents of which are hereby incorporated by reference.

### BACKGROUND OF THE INVENTION

1. Field of the Invention

The present general inventive concept relates to an apparatus to treat a wafer, a method of treating a wafer and a semiconductor package fabricated by the same, and more particularly, to an apparatus to saw a wafer and having a nozzle to remove burrs in scribe lanes, a method of sawing a wafer, and a semiconductor package fabricated by the same.

2. Description of the Related Art

Generally, a semiconductor chip is produced through numerous semiconductor processes on a wafer and fabricated in a semiconductor process line. The semiconductor chip may have integrated circuits formed on the wafer through the numerous semiconductor processes. And in a case that the semiconductor chip is packaged in order to function as semiconductor products, the semiconductor chip should be separated from the wafer in order to be packaged.

FIG. 1A is a perspective view illustrating a conventional method of sawing a wafer 10, and FIG. 1B is a cross-sectional view illustrating a semiconductor package having a semiconductor chip fabricated according to a conventional packaging method.

Referring to FIG. 1A, the wafer 10 may includes semiconductor chips 12, and scribe lanes 14 for defining the semiconductor chips 12. The semiconductor chips 12 may include conductive pads 16 therein. Metal pads 18 may be also disposed in the scribe lanes 14. In order to separate the semiconductor chips 12 from the wafer 10, the wafer 10 may be cut along the scribe lanes 14 using a blade 20 of an apparatus (not shown) for sawing the wafer 10. The blade 20 may have a width smaller than the scribe lanes 14. The blade 20 moves in a predetermined direction along the scribe lanes 14 to cut the wafer 10 as many as the semiconductor chips 12. In this case, the scribe lanes 14 may be cut together with the metal pads 18 disposed therein. Portions of the metal pads 14 may be left in the scribe lanes 14 to make burrs 22 adjacent to the semiconductor chips 12 as shown in a region ‘A’. The burrs may be projected upwardly from edges of the semiconductor chips 12.

Referring to FIG. 1B, a package process is performed on the semiconductor chips 12 of FIG. 1A to fabricate semiconductor packages. To this end, one selected from the semiconductor chips 12 has the burrs 22 adjacent to the edge thereof as shown in the figure. The one selected semiconductor chip 12 may be mounted on a circuit board 24 and be attached to the circuit board 24 using an adhesive 30. Then, bonding wires 26 are disposed between the one selected semiconductor chip 12 and the circuit board 24 to electrically connect the conductive pads 16 and bonding pads 28 one another. A soldering element 34 is formed on the circuit board 24 to be connected to the bonding pad 28.

In addition, an encapsulation member 32 is provided to protect the semiconductor chip 12 and the bonding wires 26 from the exterior environment in order to complete the package process. In this case, the bonding wires 26 contact the burrs 22 of the metal pads 18, thus generating short-circuits of a region ‘B’ between the bonding wires 26 and the metal pads 18. In order to solve the problems, the blade 20 may be designed to have substantially the same width as the scribe lanes 14 to entirely remove the burrs 22. However, since the semiconductor chip 12 may also be damaged during the cutting of the wafer 10 using the blade 20, a margin of the package process is reduced, inferiority of the package process causes malfunction of the one selected semiconductor chip 12, and thereby lowering reliability of the one selected semiconductor device 12.

### SUMMARY OF THE INVENTION

The present general inventive concept provides an apparatus to saw a wafer and remove burrs generated in scribe lanes during cutting the wafer to improve reliability of a semiconductor device.

The present general inventive concept also provides a method of sawing a wafer capable of removing burrs generated in scribe lanes during cutting the wafer to improve reliability of a semiconductor device.

The present general inventive concept also provides a semiconductor package having conductive pads in a semiconductor chip and dummy metal pads free of burrs in a scribe lanes adjacent to the semiconductor chip.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing an apparatus to saw a wafer. The apparatus may include a blade to cut scribe lanes of the wafer. The scribe lanes have sawing lanes and metal pads on the sawing lanes. The wafer contacts the blade through the sawing lanes and has cut metal pads adjacent to the blade. The cut metal pads have burrs thereon. The apparatus may further include at least one burr removing nozzle disposed spaced apart from the blade. The at least one burr removing nozzle may face the cut metal pads with a predetermined injection angle with respect to an upper surface of the wafer.

The at least burr removing nozzle may eject a burr removing solution toward the burrs to bend the burrs downwardly or cut the burrs from the cut metal pads.

The burr removing solution may include deionized water.

The injection angle may be in the range of 0° to 90° with respect to the upper surface of the wafer.

The at least one burr removing nozzle may move to the same direction as the blade to inject a solution with the injection angle.

The at least one burr removing nozzle may be disposed at both sides of the blade.

The cut metal pads may be exposed to the sawing lanes.

The metal pads may include at least one selected from a test element group key, an alignment key, and an open/sort key.

The apparatus may further include side nozzles to eject a cleaning/cooling solution to side surfaces of the blade and an upper surface of a cut part of the wafer.

The apparatus may further include a cooling nozzle and a cleaning nozzle. The cooling nozzle may be disposed behind the blade and may eject a cooling solution toward the blade. The cleaning nozzle may eject a cleaning solution toward a cut part of the wafer.

The foregoing and/or other aspects and utilities of the present general inventive concept may also be achieved by providing a method of sawing a wafer. The method may include cutting scribe lanes of the wafer by using a blade of an apparatus for sawing the wafer. The scribe lanes have sawing lanes and metal pads on the sawing lanes. The blade moves along the sawing lanes. The wafer has cut metal pads during the cutting of the scribe lanes. The cut metal pads have burrs. The method may further include injecting a burr removing solution to the cut metal pads with a predetermined injection angle with respect to an upper surface of the wafer by using apparatus for sawing the wafer during the cutting of the scribe lanes.

The burr removing solution may be ejected toward the burrs to bend the burrs downwardly or cut the burrs from the cut metal pads.

The burr removing solution may include deionized water.

The injection angle may be in the range of 0° to 90° with respect to the upper surface of the wafer.

The burr removing solution may be ejected with the injection angle.

The burr removing solution may be ejected from both sides of the blade.

The cut metal pads may be exposed to the sawing lanes.

The metal pads may include at least one selected from a test element group key, an alignment key, and an open/sort key.

The method may further include injecting a cleaning/cooling solution to side surfaces of the blade and an upper surface of a cut part of the wafer by using side nozzles of the apparatus for sawing the wafer.

The method may further include ejecting a cooling solution toward the blade from behind the blade using a cooling nozzle of the apparatus for sawing the wafer, and ejecting a cleaning solution toward a cut part of the wafer using a cleaning nozzle of the apparatus for sawing the wafer.

The foregoing and/or other aspects and utilities of the present general inventive concept may also be achieved by providing a semiconductor package. The semiconductor package may comprise a semiconductor chip, cut scribe lanes, a circuit board and external lines. The semiconductor chip may have conductive pads. The cut scribe lanes may have dummy metal pads. The cut scribe lanes may surround the semiconductor chip and may be protruded from the semiconductor chip. The dummy metal pads have shapes free of burrs thereon. The circuit board may be disposed under the semiconductor chip and the cut scribe lanes. The circuit board may have bonding pads. The external lines may electrically connect the semiconductor and the circuit board through the conductive and bonding pads. The external lines may at least traverse upper portions of the dummy metal pads.

The external lines may be conductive bumps, and the conductive bumps may be formed among the conductive and bonding pads.

The external lines may be bonding wires, and the bonding wires may be formed to contact the conductive and bonding pads and to traverse the upper potions of the dummy metal pads.

The foregoing and/or other aspects and utilities of the present general inventive concept may also be achieved by providing a semiconductor package including a semiconductor chip having a cutting metal pad having a first thickness and a burr having a second thickness smaller than the first thickness.

The semiconductor chip may include a major surface on which a conductive pad and a metal pad are formed, and a cutting surface on which the cutting metal pad are formed from the metal pad, and the burr protrudes from the major surface in a direction of the cutting surface by the second thickness.

The semiconductor chip may include a major surface on which a conductive pad and a metal pad are formed, and a cutting surface on which the cutting metal pad are formed from the metal pad, and the burr protrudes from the cutting surface in a direction of the major surface by the second thickness.

The semiconductor package may further include a circuit board and a conductive element to connect the semiconductor chip and the circuit board, and wherein the burr may not protrude toward the conductive element more than the second thickness.

The semiconductor package may further include an insulation layer, and the conductive element may be disposed within the insulation layer, and at least a portion of the burr is deformed, bent, or removed such that the second thickness is smaller than the first thickness of the cutting metal pad.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1A is a perspective view illustrating a conventional method of sawing a wafer.

FIG. 1B is a cross-sectional view illustrating a semiconductor package having a semiconductor chip fabricated according to a conventional sawing/packaging method.

FIG. 2 is a perspective view illustrating an apparatus to saw a wafer according to an exemplary embodiment of the present general inventive concept.

FIG. 3 is an enlarged perspective view illustrating a region ‘D’ of FIG. 2.

FIG. 4 is a flowchart illustrating a method of sawing a wafer according to an exemplary embodiment of the present general inventive concept.

FIGS. 5A, 5B, 5C, 5D, and 5E are a perspective view and a cross-sectional view illustrating an operation of an apparatus to saw a wafer and to treat burr according to an exemplary embodiment of the present general inventive concept.

FIGS. 6A and 6B are cross-sectional views illustrating a semiconductor package having a semiconductor chip fabricated according to an exemplary embodiment of the present general inventive concept.

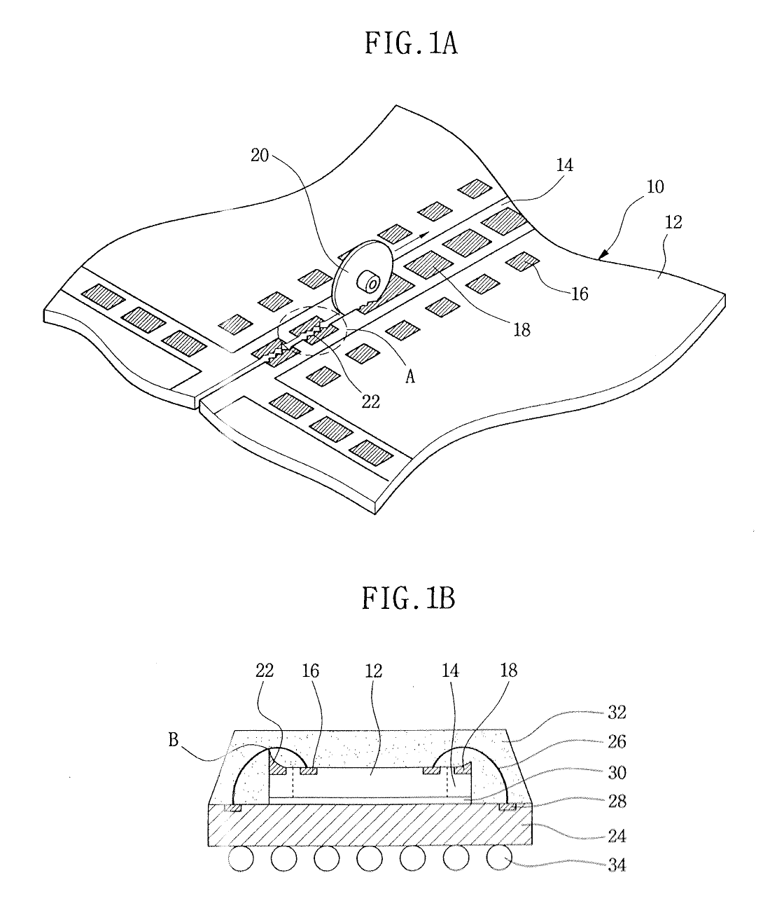

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures

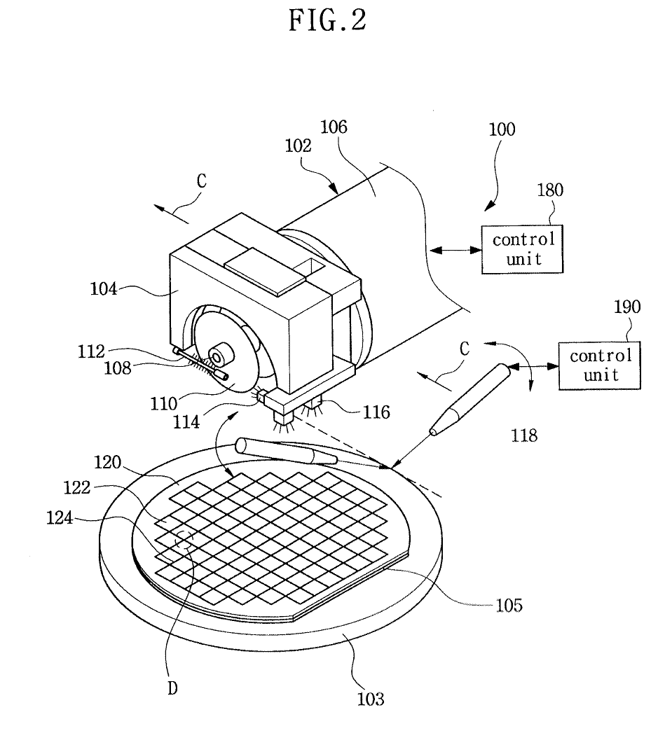

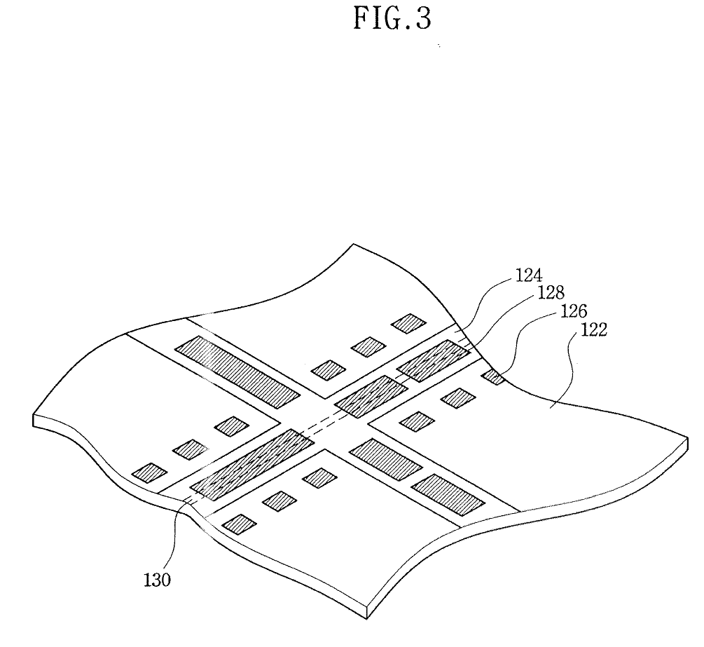

An apparatus to saw a wafer and to treat or remove burr according to an exemplary embodiment of the present general inventive concept will be described with reference to FIGS. 2 and 3.

Referring to FIGS. 2 and 3, an apparatus 100 includes a cutting part 102 to cut a wafer 120, and a support part 103 to support the wafer 120. The support part 103 may have an adhesive tape 105 disposed thereon. The wafer 120 may be disposed on the adhesion tape 105 and be fixed to the support part 103. Here, as shown in FIG. 3, the wafer 120 includes a plurality of semiconductors chips 122, and one or more scribe lanes 124 to define the semiconductors chips 122 and to provide one or more sawing lanes 130.

The semiconductors chips 122 may include one or more integrated circuits, for example, a memory device such as a dynamic random access memory (DRAM) device, a flash memory device, a static random access memory (SRAM) device, or a phase-change random access memory (PRAM) device, or a non-memory device such as a logic device. It is possible that the semiconductors chips 122 may include one or more discrete devices such as transistors, resistors and/ or capacitors. The semiconductors chips 122 may also include an interconnection t connect the discrete devices one another, and may further include conductive pads 126. The conductive pads 126 may electrically contact the interconnection. In addition, the conductive pads 126 may contact conductive bumps (not illustrated) stacked thereon.

Meanwhile, the scribe lanes 124 may include the sawing lanes 130 and one or more metal pads 128 as illustrated in FIG. 3. The sawing lanes 130 have a width smaller than the scribe lanes 124. The metal pads 128 may be disposed in the scribe lanes 124. The metal pads 128 are disposed to overlap the sawing lanes 130, and have a width larger than the sawing lanes 130. The conductive and metal pads 126 and 128 may be directly exposed to an outside thereof or disposed in an insulating layer (not illustrated) which is deposited on the wafer 120. The conductive and metal pads 126 and 128 may be formed of a metal layer such as an aluminum layer. The metal pads 128 may be provided as various keypads, and may include at least one selected from, for example, a test element group key, an alignment key, and an open/sort key.

Further, as illustrated in FIG. 2, the cutting part 102 may include a blade 110 which is formed of diamond. The blade 110 may be rotated by a rotary shaft 108. The rotary shaft 108 is electrically coupled to a motor 106 which is engaged with a fixing cover 104. In this case, the blade 110 may be designed to have substantially the same width as the sawing lanes 130. The blade 110 may move in a predetermined moving direction C along the sawing lanes 130 to cut the wafer 120 and the scribe lanes 124. The blade 110 may cut the wafer 120 as many as the semiconductor chips 122. In addition, the blade 110 may cut the metal pads 128 together with the scribe lanes 124. That is, the cut metal pads 128 may exist in the cut scribe lanes 124. The cut metal pads 128 may have burrs projecting upwardly from edges of the semiconductor chips 122.

The apparatus 100 may further include side nozzles 112 disposed at both sides of the blade 110, a cooling nozzle 114 disposed behind the blade 110 with reference to the moving direction C, and a cleaning nozzle 116 disposed under the cooling nozzle 114 as shown in FIG. 2. During the cutting of the wafer 120, friction between the wafer 120 and the blade 110 may generate heat, damaging the integrated circuits of the semiconductor chips 122. In addition, particles may be generated during the cutting of the wafer 120. In order to prevent increase in temperature of the wafer 120 and remove the particles, the side nozzles 112 and the cooling nozzle 114 can eject (inject) a predetermined amount of liquid to the wafer 120 and the blade 110. Specifically, the side nozzles 112 can eject a cleaning/cooling solution to side surfaces of the blade 110 and an upper surface of a cut part of the wafer 120.

The cooling nozzle 114 can eject a cooling solution to the blade 110 from behind the blade 110 with reference to the moving direction C. The cleaning/cooling solution and the cooling solution ejected from the side nozzles 112 and the cooling nozzle 114 may include deionized water. In addition, the cleaning nozzle 116 can eject (inject) a cleaning solution to the cut part of the wafer 120 from behind the cooling nozzle 114 with reference to the moving direction. The cleaning nozzle 116 can function to remove the particles mounted on the cut scribe lanes 124 and the semiconductor chips 122 adjacent to the cut scribe lanes 124, together with the side nozzles 112 during the cutting of the wafer 120. The cleaning solution may use the same liquid as that used in the side nozzles 112 and the cooling nozzle 114.

Meanwhile, burr removing nozzles 118 may be disposed spaced apart from the blade 110 and disposed adjacent to both sides of the blade 110 with reference to the moving direction C as illustrated in FIG. 2. The burr removing nozzle 188 moves to the same direction as the blade 110 or a different direction from the blade 110. The burr removing nozzle 118 may be disposed to face the cut metal pads 128 with a predetermined ejection (injection) angle with respect to an upper surface of the wafer in order to effectively remove one or more burrs depending on their shapes. The injection angle may be in the range of 0° to 90° with respect to the upper surface of the wafer. The burr removing nozzles 118 can eject (inject) a burr removing solution to the burrs remained in the cut scribe lanes 124 after the blade 110 passes the cut scribe lanes. In this case, the burr removing solution may include, for example, deionized water, the same liquid as that used in the side nozzles 112. The burr removing solution may be ejected to a higher water pressure than the cleaning/cooling solution and the cleaning solution. The burr removing solution may be ejected with a predetermined pressure to treat, cut, bend, deform, or remove the burr.

As a result, the burr removing nozzles 118 can downwardly bend or cut the burrs from the cut metal pads 128 during the cutting of the wafer 120, thereby removing the burrs. In addition, the burr removing nozzles 118 can move over the wafer 120 in the range of the injection angle to effectively bend or cut the burrs during the removal of the burrs. In the exemplary embodiment, while the burr removing nozzles 118 are disposed at both sides of the blade 110 with respect to the moving direction C, but not limited thereto, at least one burr removing nozzle may be disposed at one side of the blade 110.

As illustrated in FIG. 2, the apparatus 100 may further include a first control unit 180 to control the motor 106 to rotate the blade 110, to control the side nozzles 112, the cooling nozzle 114, and the cleaning nozzle 116 to inject or eject the corresponding solution in timely manner according to a cutting operation of the blade 110, and to control the cutting part 102 to relatively move along a rail (not illustrated) in the direction C with respect to the supporting part 103.

The apparatus may also include a second control unit 190 to control burr removing nozzles 118 to move along the cutting part of the wafer 120. The burr removing nozzles 118 may be connected to the cutting part 102 through a connector (not illustrated). However, it is possible that the burr removing nozzles 118 may not be connected but may independently move along the cutting part of the wafer 120. The burr removing nozzles 118 may be mounted on a transfer unit (not illustrated) which may be controlled by the second control unit 190 to move along a rail (not illustrated) in a direction of the cutting part of the wafer 120. The burr removing nozzles 118 may rotate with respect to the cutting part of the wafer in a direction perpendicular to the direction C. Therefore, the second control unit 190 moves the burr removing nozzles 118 of the transfer unit in the direction C and rotates the burr removing nozzles 118 of the transfer unit with respect to the burrs. The pressurized liquid of the burr removing nozzles 118 can remove, cut, or deform the burrs according to their shapes and characteristics with respect to the cutting part of the wafer 120. Accordingly, the original shape of the burrs formed after the cutting operation of the cutting part 102 is changed to a shape without the burrs or a shape different from the original shape such that the changed shape does not contact a bonding wire.

The first control unit 180 and the second control unit 190 may be formed in a single control unit to control both the cutting part 102 and the burr removing nozzles 118.

Hereinafter, a method of sawing a wafer according to an exemplary embodiment of the present general inventive concept will be described with reference to FIGS. 2, 4, 5A, and 5B.

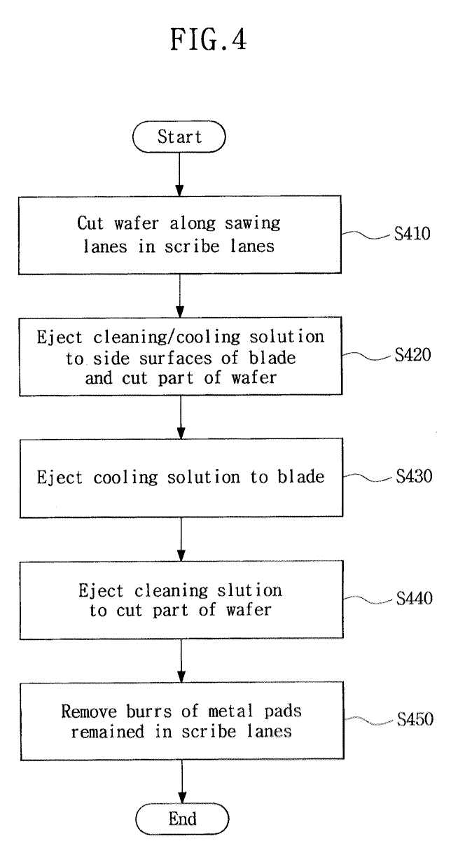

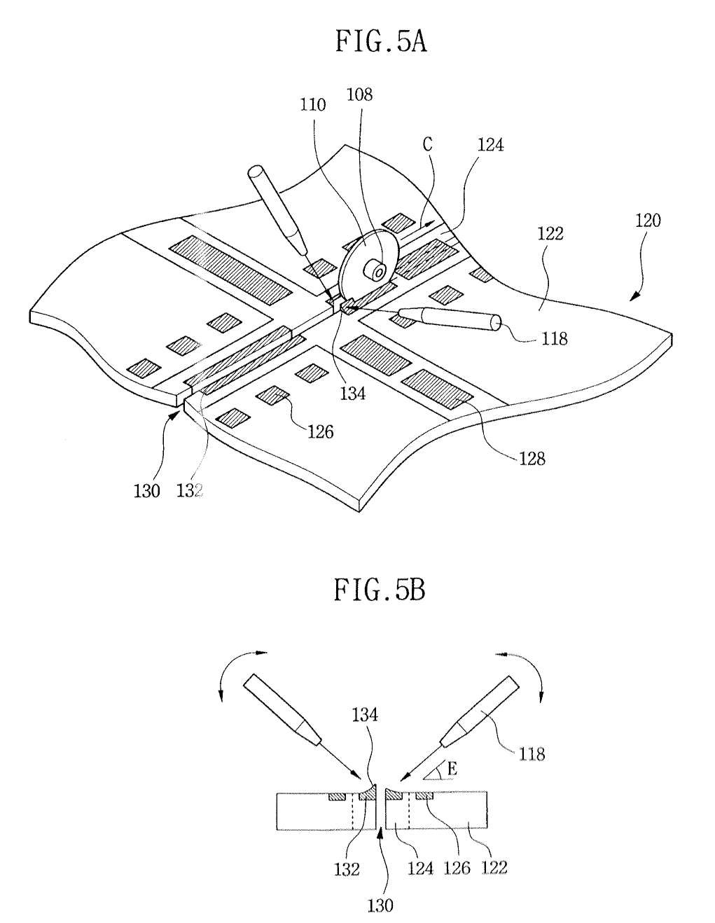

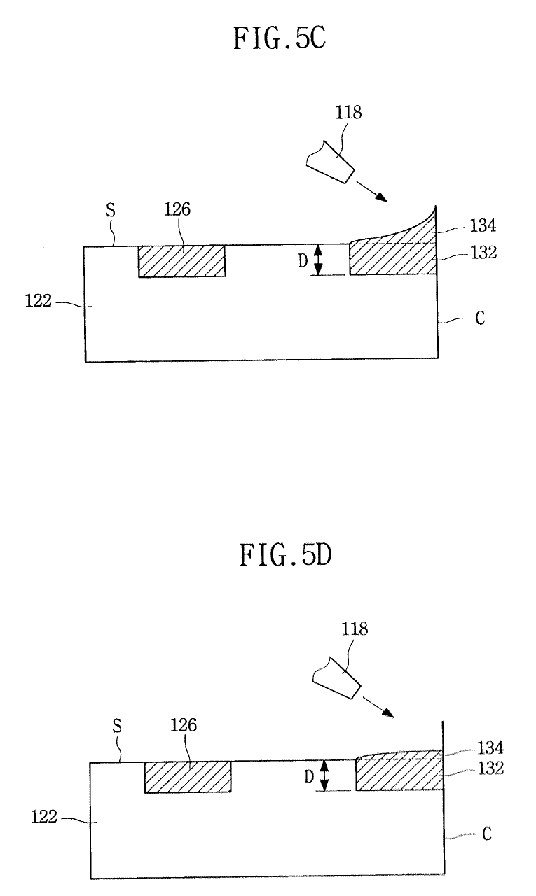

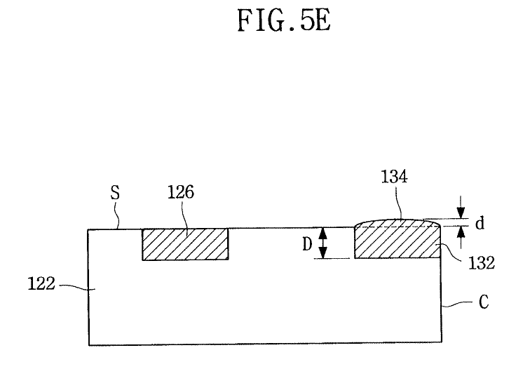

FIG. 4 is a flowchart illustrating a method of sawing a wafer according to an exemplary embodiment of the present general inventive concept. And FIGS. 5A and 5B are a perspective view and a cross-sectional view illustrating an operation of an apparatus to saw a wafer according to an exemplary embodiment of the present general inventive concept. FIGS. 5C, 5D, and 5E are views illustrating the semiconductor chip 122 and the burrs treated, cut, bent, removed, or deformed burrs by an operation of the burr removing nozzles 118.

Referring to FIGS. 2 to 5B, a wafer 120 may be mounted to the adhesion tape 105 and be fixed to the support part 103 as shown in FIG. 2. The wafer 120 may include semiconductor chips 122 and scribe lanes 124 as shown in FIG. 5A. The semiconductor chips 122 may include conductive pads 126 and conductive bumps (not illustrated) stacked thereon. The scribe lanes 124 include sawing lanes 130 and metal pads 128. The sawing lanes 130 may have a width smaller than the scribe lanes 124. The metal pads 128 may be disposed to overlap the sawing lanes 130 and have a width larger than the sawing lanes 130.

The wafer 120 may be cut by using the blade 110 as shown in FIG. 5A, in operation S410. The blade 110 may have substantially the same width as the sawing lanes 130. The blade 110 may be moved to a predetermined moving direction C along the sawing lanes 130. The scribe lanes 124 may be cut on the wafer 120 to form cut scribe lanes 124. The metal pads 128 may be also cut together with the cut scribe lanes 124 to form the cut metal pads 132 as illustrated in FIGS. 5A and 5B. The cut metal pads 132 may have burrs 134 adjacent to the semiconductor chips 122 as illustrated in FIG. 5B. As a result, the semiconductor chips 122 may be separated from the wafer 120. Then, during the cutting of the wafer 120, a cleaning/cooling solution may be injected to side surfaces of the blade 110 and an upper surface of a cut part of the wafer 120 using a side nozzles 112 as illustrated in FIG. 2, in operation S420 of FIG. 4.

Continuously, a cooling solution may be injected to the blade 110 using a cooling nozzle 114 as illustrated in FIG. 2, in operation S430 of FIG. 4. Therefore, it is possible to suppress increase in temperature of the wafer 120 and particles generated during the cutting of the wafer 120 using the side nozzles 112 and the cooling nozzle 114. Here, a cleaning solution may be injected to the cut part of the wafer 120 using a cleaning nozzle 116 as illustrated in FIG.2, in operation S440 of FIG. 4. As such, the side nozzles 112, the cooling nozzle 114 and the cleaning nozzle 116 may remove particles from the semiconductor chips 122 and the cut scribe lanes 124 during the cutting of the wafer 120.

Next, the burrs 134 remained in the divided scribe lanes 123 are removed using a burr removing nozzles 118 as illustrated in FIG. 2, in operation S450 of FIG. 4. In this case, the removal of the burrs 134 means to downwardly bend or cut the burrs 134 from the cut metal pads 132 as shown in FIGS. 5A and 5B. That is to say, the burrs 134 may be downwardly bent in an opposite direction of the conductive pads 126 to be spaced apart from the conductive pads 126 during the removal of the burrs 134. The cut metal pads 132 may have substantially the same level as the conductive pads 126. Upper surfaces of the cut metal pads 132 may have shapes free of the burrs 134.

Meanwhile, in order to remove the burrs 134, the burr removing nozzles 118 can inject a burr removing solution at a predetermined injection angle E with respect to the upper surface of the wafer 120 as illustrated in FIG. 5B. The injection angle E may have an angle of 0° to 90° with respect to an upper surface of the wafer 120 in order to effectively remove the burrs 134 depending on shapes thereof. In addition, the burr removing nozzles 118 can move in the range of the injection angle E to effectively bend or cut the burrs 134 from the cut metal pads 132 while removing the burrs 134. While the burr removing nozzles 118 may be disposed at both sides of the blade 110 with reference to the moving direction C, not limited thereto, at least one nozzle may be disposed at one side of the blade 110.

As illustrated in FIG. 5C, the semiconductor chip 122 may have the cut metal pad 132 with the burr 134. However, since the burr 134 protrudes from a major surface S of the semiconductor chip 122, the burr 134 can be removed from cut metal pad 132. As illustrated in FIG. 5D, the burr 134 may be bent from its original shape, which protrudes toward a direction to contact a bonding wire, to a bent shape, which does not protrude in a direction perpendicular to the major surface S or parallel to the cut surface C or which is different from its original shape. As illustrated in FIG. 5E, the burr 134 may be deformed to have a thickness d thinner than a thickness D of the cut metal pad 132 in a direction parallel to a cut surface C or perpendicular to the major surface S of the semiconductor chip 122. However, the present general inventive concept is not limited thereto. According to the ejecting operation of the burr removing nozzles 118, the burr 134 may be treated in other manners. After the above-described burr removing process, a semiconductor package may include a semiconductor chip to have a cutting metal pad having a first thickness and a burr having a second thickness smaller than the first thickness.

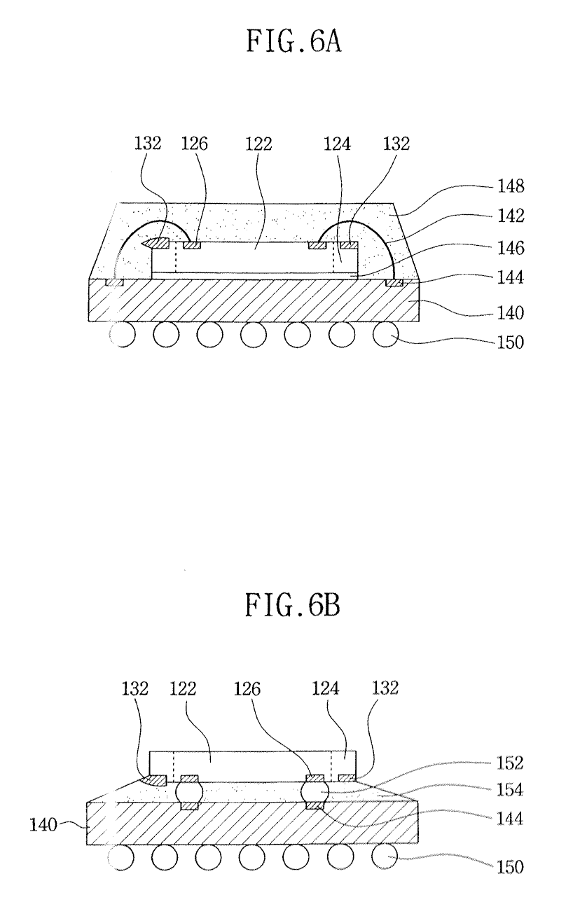

After completing the cutting of the wafer 120, the semiconductor chips 122 and the cut scribe lanes 124 may be packaged to form semiconductor packages through a package process. Hereinafter, a semiconductor package including a semiconductor chip will be described with reference to FIGS. 6A and 6B. FIGS. 6A and 6B are cross-sectional views showing a semiconductor package having a semiconductor chip fabricated in accordance with an exemplary embodiment of the present invention.

Referring to FIG. 6A, a semiconductor chip 122 and a cut scribe lanes 124 protruded from the semiconductor chip 122 may be provided. The semiconductor chip 122 may have conductive pads 126 thereon. The cut scribe lanes 124 may have cut metal pads 132 thereon. The cut metal pads 132 become dummy metal pads, which are not electrically connected to the circuit board 140. The semiconductor chip 122 and the cut scribe lanes 124 may be mounted on a circuit board 140 such as a printed circuit board. The circuit board 140 may have a bonding pads 144 thereon. An adhesive 146 may be formed between the semiconductor chip 122, the cut scribe lanes 124 and the circuit board 140. An external lines may be formed to electrically connect the semiconductor chip 122 and the circuit board 140 each other. The external lines may be bonding wires 142. At this time, the conductive pads 126 may contact the bonding pad 144 through the bonding wires 142. The bonding wires 142 may traverse upper portions of the dummy metal pads. One or more external terminals (or soldering elements) 150 are formed on the circuit board 140 to be electrically connected to a circuit of the semiconductor chip 122 through the bonding pad 144, the bonding wire 142, and the conductive pad 126, for example.

The semiconductor chip 122 can receive power or electrical signals through solder balls 150 provided on a lower surface of the circuit board 140. An insulation layer, for example, encapsulation member 148, is formed on the circuit board 140 to protect the semiconductor chip 122 and the bonding wires 142 from the exterior environment. As such, the semiconductor chip 122, the cut scribe lanes 124 and the circuit board 140 may constitute a semiconductor package 122 together with the encapsulation member 148. In this case, the cut metal pads 132 do not have burrs 134 of FIGS. 5A and 5B projecting upwardly from edges of the semiconductor chip 122 because of the removal of the burrs 134 from upper surfaces of the cut metal pads 132. Accordingly, the cut metal pads 132 may have substantially the same level as the conductive pads 126. Therefore, short circuit between the bonding wires 142 and the cut metal pads 132 may be prevented to improve reliability of the semiconductor device 122.

Referring to FIG. 6B, a semiconductor chip 122 and a cut scribe lanes 124 protruded from the semiconductor chip 122 may be provided. The semiconductor chip 122 and the cut scribe lanes 124 may have the elements as FIG. 6A. Then, the semiconductor chip 122 and the cut scribe lanes 124 may be mounted on a circuit board 140 such as a printed circuit board. The circuit board 140 may have one or more bonding pads 144 thereon. An external line may be formed between the semiconductor chip 122 and the circuit board 140. The external line may be a conductive bump 152. The conductive bump 152 may be formed to electrically connect the semiconductor chip 122 and the circuit board 140 each other. An insulation layer, for example, under-fill 154, may be formed among the semiconductor chip 122, the cut scribe lanes 124 and the circuit board 140. As such, the semiconductor chip 122, the cut scribe lanes 124 and the circuit board 140 may constitute a semiconductor package 122 together with the under-fill 154. In this case, the cut scribe lanes 124 do not have the burrs 134 of the cut metal pads 132 of FIGS. 5A and 5B. Accordingly, the semiconductor chip 122 and the circuit board 140 do not have leakage current path to the cut scribe lanes 124 through the cut metal pads 132.

As can be seen from the foregoing, an apparatus to saw a wafer includes a burr removing nozzle disposed adjacent to a blade therein. The burr removing nozzle removes burrs of cut metal pads in cut scribe lanes during cutting a wafer, thereby improving reliability of a semiconductor package.

Although a few embodiments of the present general inventive concept have been shown and described, it would be appreciated by those skilled in the art that changes may be made in this embodiment without departing from the principles and spirit of the general inventive concept, the scope of which is defined in the claims and their equivalents.

What is claimed is:

1. An apparatus to saw a wafer, comprising:
a blade to cut one or more scribe lanes of the wafer, the scribe lanes having sawing lanes and metal pads on the sawing lanes, the blade to contact the wafer through the sawing lanes such that the metal pads are changed to one or more cut metal pads formed by the blade to have one or more burrs thereon; and
at least one burr removing nozzle disposed spaced apart from the blade to face the cut metal pads with a predetermined injection angle with respect to an upper surface of the wafer to treat the burrs.

2. The apparatus of claim 1, wherein the at least burr removing nozzle ejects a burr removing solution toward the burrs to bend the burrs downwardly or cut the burrs from the cut metal pads.

3. The apparatus of claim 2, wherein the burr removing solution includes deionized water.

4. The apparatus of claim 1, wherein the injection angle is in the range of 0° to 90° with respect to the upper surface of the wafer.

5. The apparatus of claim 4, wherein the at least one burr removing nozzle moves to the same direction as the blade to inject a solution with the injection angle.

6. The apparatus of claim 1, wherein the at least one burr removing nozzle is disposed at both sides of the blade.

7. The apparatus of claim 1, wherein the cut metal pads are exposed to the sawing lanes.

8. The apparatus of claim 1, wherein the metal pads comprise at least one selected from a test element group key, an alignment key, and an open/sort key.

9. The apparatus of claim 1, further comprising:
side nozzles to inject a cleaning/cooling solution to side surfaces of the blade and an upper surface of a cut part of the wafer.

10. The apparatus of claim 1, further comprising:
a cooling nozzle disposed behind the blade to eject a cooling solution toward the blade; and
a cleaning nozzle to eject a cleaning solution toward a cut part of the wafer.

11. A method of sawing a wafer comprising:
cutting scribe lanes of the wafer by using a blade of an apparatus for sawing the wafer, the scribe lanes have sawing lanes and metal pads on the sawing lanes, the blade moves along the sawing lanes, the wafer has cut metal pads during the cutting of the scribe lanes, and the cut metal pads have burrs; and
ejecting a burr removing solution to the cut metal pads with a predetermined injection angle with respect to an upper surface of the wafer by using apparatus for sawing the wafer during the cutting of the scribe lanes.

12. The method of claim 11, wherein the burr removing solution is ejected toward the burrs to bend the burrs downwardly or cut the burrs from the cut metal pads.

13. The method of claim 12, wherein the burr removing solution includes deionized water.

14. The method of claim 11, wherein the ejection angle is in the range of 0° to 90° with respect to the upper surface of the wafer.

15. The method of claim 14, wherein the burr removing solution is ejected with the ejection angle.

16. The method of claim 11, wherein the burr removing solution is ejected from both sides of the blade.

17. The method of claim 11, wherein the cut metal pads are exposed to the sawing lanes.

18. The method of according to claim 11, wherein the metal pads comprise at least one selected from a test element group key, an alignment key, and an open/sort key.

19. The method of claim 11, further comprising:
ejecting a cleaning/cooling solution to side surfaces of the blade and an upper surface of a cut part of the wafer by using side nozzles of the apparatus for sawing the wafer.

20. The method of claim 11, further comprising,
ejecting a cooling solution toward the blade from behind the blade using a cooling nozzle of the apparatus for sawing the wafer; and
ejecting a cleaning solution toward a cut part of the wafer using a cleaning nozzle of the apparatus for sawing the wafer.

21. A semiconductor package comprising:
a semiconductor chip having conductive pads;
cut scribe lanes having dummy metal pads, the cut scribe lanes surrounding the semiconductor chip and being protruded from the semiconductor chip, and the dummy metal pads having shapes free of burrs thereon;
a circuit board disposed under the semiconductor chip and the cut scribe lanes, the circuit board having bonding pads; and
external lines electrically connecting the semiconductor and the circuit board through the conductive and dummy metal pads, the external lines at least traversing upper portions of the dummy metal pads.

22. The semiconductor package of claim 21, wherein in the case that the external lines are conductive bumps, the conductive bumps are formed among the conductive and bonding pads.

23. The semiconductor package of claim 21, wherein the external lines are bonding wires, and the bonding wires are formed to contact the conductive and bonding pads and to traverse the upper potions of the dummy metal pads.

24. A semiconductor package comprising:
a semiconductor chip having a cutting metal pad having a first thickness and a burr having a second thickness smaller than the first thickness.

25. The semiconductor package of claim 24, wherein the semiconductor chip comprises a major surface on which a conductive pad and a metal pad are formed, and a cutting surface on which the cutting metal pad are formed from the metal pad, and the burr protrudes from the major surface in a direction of the cutting surface by the second thickness.

26. The semiconductor package of claim 24, wherein the semiconductor chip comprises a major surface on which a conductive pad and a metal pad are formed, and a cutting surface on which the cutting metal pad are formed from the metal pad, and the burr protrudes from the cutting surface in a direction of the major surface by the second thickness.

27. The semiconductor package of claim 24, further comprising:
a circuit board; and
a conductive element to connect the semiconductor chip and the circuit board,
wherein the burr does not protrude toward the conductive element more than the second thickness.

28. The semiconductor package of claim 27, further comprising:
an insulation layer,
wherein the conductive element is disposed within the insulation layer, and at least a portion of the burr is deformed, bent, or removed such that the second thickness is smaller than the first thickness of the cutting metal pad.
